(19) United States
(12) Patent Application Publication
(10) Pub. No.: US 2011/0256308 A1
(43) Pub. Date: Oct. 20, 2011

(54) ALGORITHMIC PROCESSING TO CREATE FEATURES

(76) Inventor: WALTER Richard BUERGER, JR., Oxnard, CA (US)

(21) Appl. No.: 13/048,867

(22) Filed: Mar. 15, 2011

Related U.S. Application Data
(63) Continuation of application No. 12/009,402, filed on Jan. 17, 2008, now abandoned.
Application No. 12/009,402 is a continuation-in-part of application No. 11/515,284, filed on Sep. 1, 2006, now Pat. No. 7,335,580.
Application No. 11/515,284 is a continuation-in-part of application No. 10/424,022, filed on Apr. 25, 2003, now Pat. No. 7,118,988.
Application No. 10/424,022 is a continuation-in-part of application No. 10/223,446, filed on Aug. 19, 2002, now abandoned.
Application No. 10/223,446 is a continuation-in-part of application No. 10/035,871, filed on Dec. 26, 2001, now abandoned.
Application No. 10/035,871 is a continuation-in-part of application No. 09/821,957, filed on Mar. 30, 2001, now abandoned.

(51) Int. Cl. H05K 3/12

(52) U.S. Cl. 427/97.3

(57) ABSTRACT

Sub-lithographi lamella and pillar structures defined by larger lines or lamellae are described. A static random access memory (SRAM) cell structure is created in a three-dimensional format as a vertical stack of wired transistors. These transistors are fabricated from crystalline silicon, and supplemental wiring structure features are fabricated to comprise a circuit along the walls of a vertical pillar. The three-dimensional cell integrated circuit can be created by a single mask step. Various structural features and methods of fabrication are described in detail. Peripheral interface, a two pillar version and other supplemental techniques and structural variations are also described.

This application is a continuation of application

Ser. No. 12/009,402, filed Jan. 17, 2008, which is a continuation-in-part of application

Ser. No. 11/515,284 filed Sep. 1, 2006, now U.S. Pat. No. 7,335,580, which is a continuation-in-part of application,

Ser. No. 10/424,022, filed Apr. 25, 2003, now U.S. Pat. No. 7,118,988, which is a continuation-in- part of application

Ser. No. 10/223,446, filed Aug. 19, 2002, now abandoned, which is a continuation-in-part of application

Ser. No. 10/035,871, filed Dec. 26, 2001, now abandoned, which is a continuation-in-part of application

Ser. No. 09/821,957, filed Mar. 30, 2001, now abandoned.

The full content of parent application Ser. No. 12/009,402 is, and all applications therein incorprated by reference is, herein incorporated by reference in this application.

### FIELD OF INVENTION

The invention relates to structures and methods of fabrication for static random access memory (SRAM) integrated circuits, as well as for other integrated circuit applications, particularly those incorporating iterative arrays of like structures, such as other types of semiconductor memory, programmable logic, application specific integrated circuit (ASIC) underlays, and analogous applications including hard disks.

### BACKGROUND OF THE INVENTION

The integrated circuit and hard disk industries have been downscaling their products essentially since their inception. The technology described herein enhances this ability by manufacturing circuits well below the limits of photolithography, using special structures and fabrication methods.

Various three-dimensional integrated circuits structures have been disclosed for DRAM cell structures. An integrated circuit structure incorporating multiple vertical components was disclosed in a co-pending U.S. patent application Ser. No. 07/769,850 (with subsequent continuations-in-part).

These earlier vertical integrated circuit structures do not conveniently lend themselves to incorporation of crystalline silicon regions in the various components of a multiple semiconductor component stack, particularly where a large number of such semiconductor components are present. Fabrication of these earlier integrated circuit structures typically require a large number of photolithographic steps.

### SUMMARY OF THE INVENTION

This invention addresses the ability to fabricate such vertical stacks of components, as well as the ability to maintain crystalline regions where desired in the various components. These structures can be fabricated with as little as a single mask step.

As an object of the invention, a complex three-dimensional integrated circuit can be constructed of groups of components which include multiple transistors whose alternately doped regions are made from continuous crystal, these multiple transistors being arranged in a first axis, this first axis extending into a first dimension, where these components are interconnected by conductive circuitry extending in a plurality of axes, said plurality of axes extending into second and third dimensions.

As an object of the invention, a three-dimensional integrated circuit can be created by as little as one mask step.

[As an object of the invention, features may be fabricated at various locations on one or two vertical pillars which form elements of components of a larger integrated circuit.

It is an object of the invention to provide new capabilities for interconnecting and accessing circuitry formed below the photolithographic limit to conventional circuitry formed at or above the photolithographic limit, as well as the creation of unusually small electronic structures which can be used in various applications.

### BRIEF DESCRIPTION OF THE DRAWINGS

FIG. 1 is a conventional schematic of the subsequently described SRAM cell.

FIG. 2 depicts the schematic of FIG. 1 in the format of the subsequently described SRAM cell.

FIGS. 3, 4 and 5 depict three mutually orthogonal cross-sections, with vertical trenches of three different widths below the windows in the masking layer, reaching down into the second-lowest semiconductor layer and leaving rectangular semiconductor pillars in between.

FIGS. 6, 7 and 8 depict three mutually orthogonal cross-sections of a preceding structure, which is the implementation of the structure of FIG. 2, more completely and detailed.

FIG. 9 depicts the cross-section of one of a set of repeating trenches in a first material.

FIG. 10 depicts the same cross-section, with a layer of a second material covering all surfaces.

FIG. 11 depicts the same cross-section, with a further layer of first material covering all surfaces.

FIG. 12 depicts the same cross-section, with the layer of first material removed from all non-vertical surfaces.

FIG. 13 depicts the same cross-section, with a further layer of second material covering all surfaces and closing the last gap in the trench.

FIG. 14 depicts the same cross-section, with ribbons of second material alternating with ribbons of first material left in the trench.

FIG. 15 depicts the same cross-section, with the first material surface below the bottom of the structures of second material, and the blades of first material removed.

FIG. 16 depicts the same cross-section, with a new layer of first material covering all surfaces.

FIG. 17 depicts the same cross-section, with a new layer of second material covering all surfaces.

FIG. 18 depicts the same cross-section, with a further layer of first material covering all surfaces.

FIG. 19 depicts the same cross-section, with the layer of first material removed from all non-vertical surfaces.

FIG. 20 depicts the same cross-section, with a further layer of second material covering all surfaces and closing the last gap.

FIG. 21 depicts the same cross-section, with ribbons of second material alternating with interstices of first material.

FIG. 22 depicts the same cross-section, with the first material removed from the interstices.

FIG. 23 depicts the same cross-section, with the bridges of second material at the bottom of the ribbons removed.

FIG. 24 depicts the same cross-section, with the interstices between the ribbons deepened into the first material at the bottom.

FIG. 25 depicts the same cross-section, with the ribbons of second material removed.

FIG. 26 and FIG. 27 depict a top view and a cross-section, respectively, of a group of ribbons of a second material on top of a substrate of a first material.

FIG. 28, FIG. 29 and FIG. 30 depict pairs of opposing pillar faces which become cross-connected.

### DESCRIPTION OF THE PREFERRED EMBODIMENT

The description of the invention described in this specification document incorporates information from a U.S. patent application Ser. No. 10/424,022 by applicants “Buerger, Walter Richard JR.; et al.,” (specifically: “Buerger, Walter Richard JR.; (Covina, Calif.); Hohl, Jakob Hans; (Tuscon, Ariz.); Long, Mary Lundgren; (Phoenix, Ariz.); Ridgeway, Kent; (Glendale, Ariz.)”), USPTO publication number 20050079721, published by the USPTO on Apr. 14, 2005, which is herein incorporated by reference. This incorporation by reference particularly includes the text discussed in the subsequently identified text portions of the aforementioned Application (publication number 20050079721).

In the following identified text portions, paragraph numbers enclosed in brackets in the published application document (20050079721) are identified in the formats “<Par. ####>” or “<through Par. ####>”, where “####” represents the paragraph numbers used in the published version. “<Par. ####>” with “<through Par. ####>” identifies additional text which is also incorporated by reference. Brackets used elsewhere in the published text to identify cross-referencing codes, etc., have been replaced in the following identifying text portions with these identifiers. Figure numbers (below) for the accompanying drawings reference the figures listed in the foregoing Brief Description of the Drawings, not the numbers in the incorporation by reference text. The text below is either excerpted from or comparable to the text in the incorporation by reference publication for the paragraphs cited.

Identified text portions incorporated by reference are as follows:

The invention relates to structures and methods of fabrication for static random access memory (SRAM) integrated circuits, as well as for other integrated circuit applications, particularly those incorporating iterative arrays of like structures, such as other types of semiconductor memory, programmable logic, application specific integrated circuit (ASIC) underlays, and analogous applications.

Various three-dimensional integrated circuits structures have been disclosed for DRAM cell structures. An integrated circuit structure incorporating multiple vertical components was disclosed in a co-pending U.S. patent application Ser. No. 07/769,850 (with subsequent continuations-in-part).

These earlier vertical integrated circuit structures do not conveniently lend themselves to incorporation of crystalline silicon regions in the various components of a multiple semiconductor component stack, particularly where a large number of such semiconductor components are present. Fabrication of these earlier integrated circuit structures typically require a large number of photolithographic steps.

This invention addresses the ability to fabricate such vertical stacks of components, as well as the ability to maintain crystalline regions where desired in the various components. These structures can be fabricated with as little as a single mask step.

As an object of the invention, a complex three-dimensional integrated circuit can be constructed of groups of components which include multiple transistors whose alternately doped regions are made from continuous crystal, these multiple transistors being arranged in a first axis, this first axis extending into a first dimension, where these components are interconnected by conductive circuitry extending in a plurality of axes, said plurality of axes extending into second and third dimensions.

As an object of the invention, a three-dimensional integrated circuit can be created by as little as one mask step.

As an object of the invention, features may be fabricated at various locations on one or two vertical pillars which form elements of components of a larger integrated circuit.

It is an object of the invention to provide new capabilities for interconnecting and accessing circuitry formed below the photolithographic limit to conventional circuitry formed at or above the photolithographic limit. <Par. 0010> <through Par. 0445>

The following Description of the Preferred Embodiment is organized into six parts: I. Considerations Regarding The Following Description, II. Fabrication Technology Used In The Following Step Sequence, m. SRAM Cell Fabrication Step Sequence, IV. Pillar Masking Techniques, V. Periphery, and VI. Supplemental Techniques & Clarifications. Part I introduces concepts, conditions and clarifications regarding the Part III step sequence. Part II explains fabrication methods used in the Part III step sequence. Part III is the fabrication step sequence itself Thus, Parts I and II provide background information regarding the step sequence(s) in Part III, and may be used for reference while reading in detail the step sequence(s) of Part III. Part IV describes techniques for creating masks which can be used to create pillars. Part V describes techniques for creating peripheral circuitry. Part VI describes various supplemental techniques and clarifications for the previously described technology.

The step sequence of Part III demonstrates that features may be fabricated at various locations on a vertical pillar which form elements of components of a larger integrated circuit. These capabilities create a basis for a three-dimensional circuit integration technology.

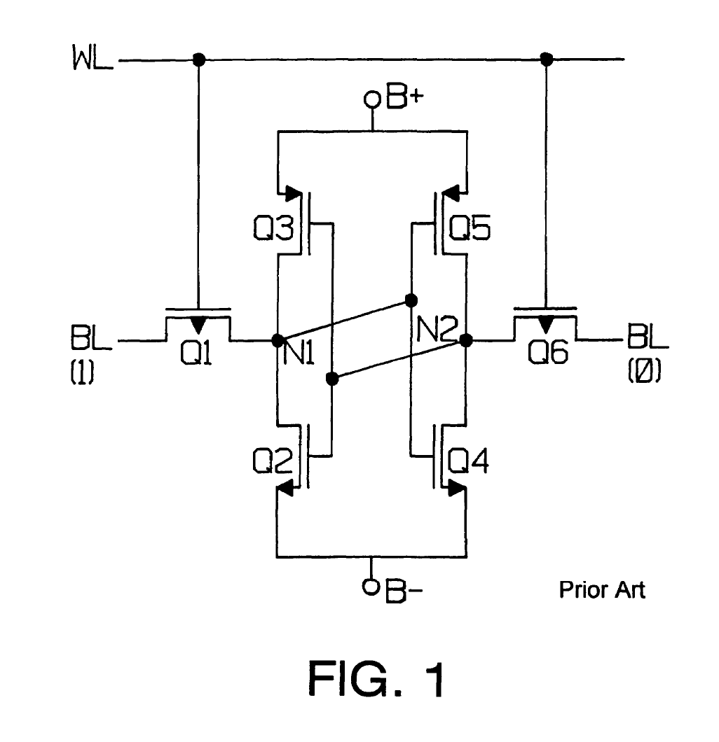

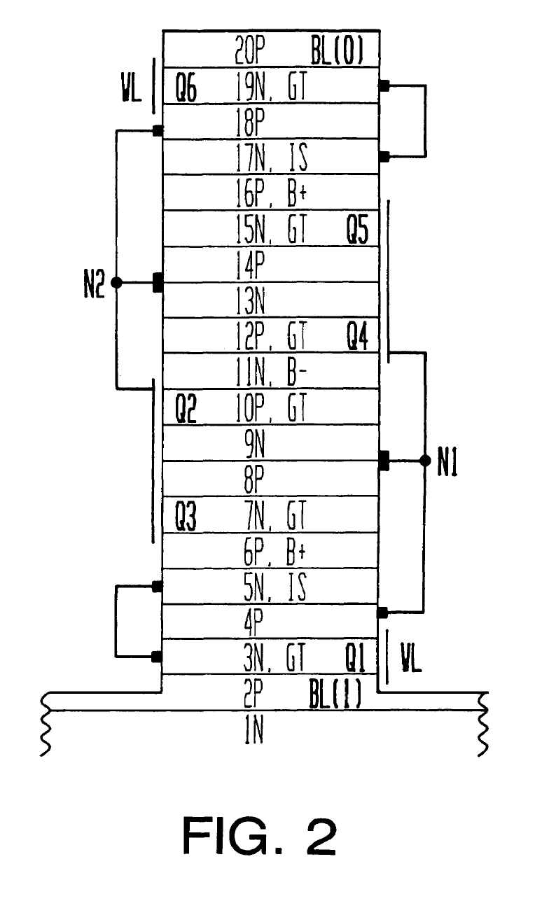

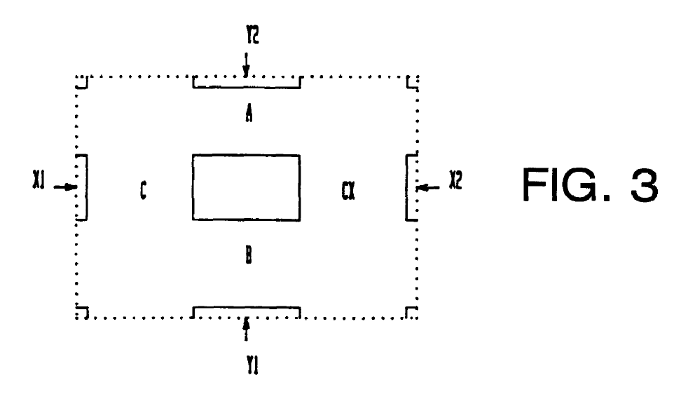

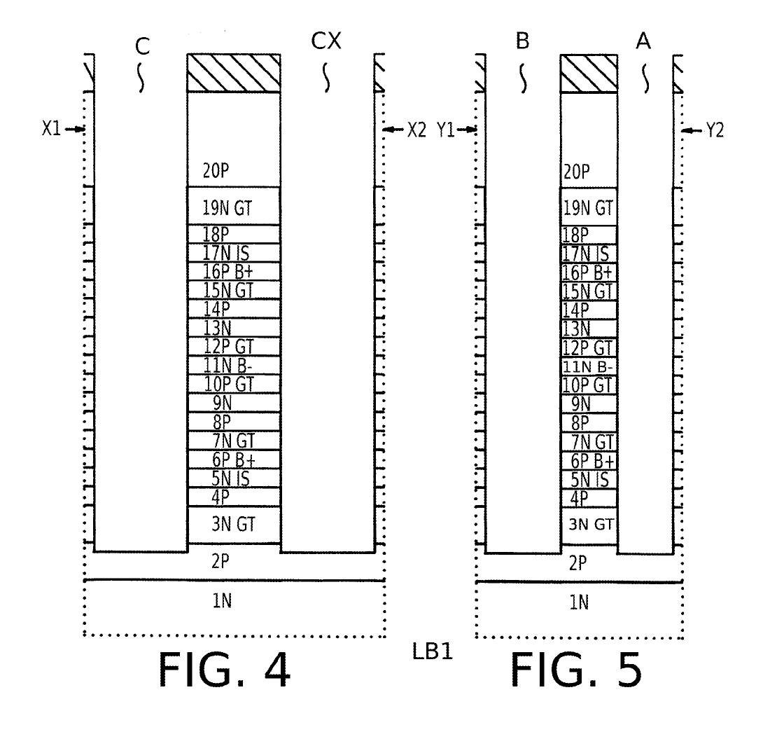

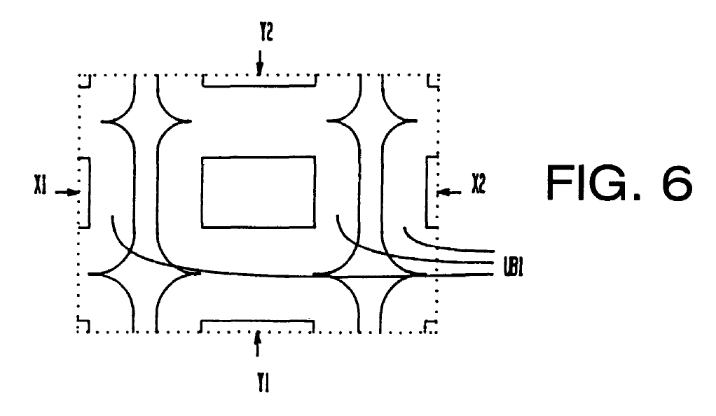

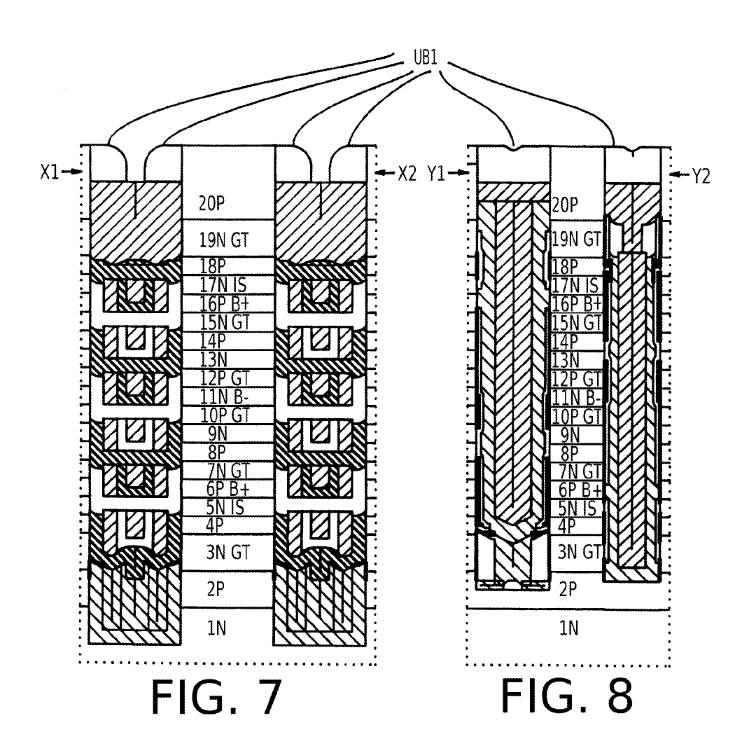

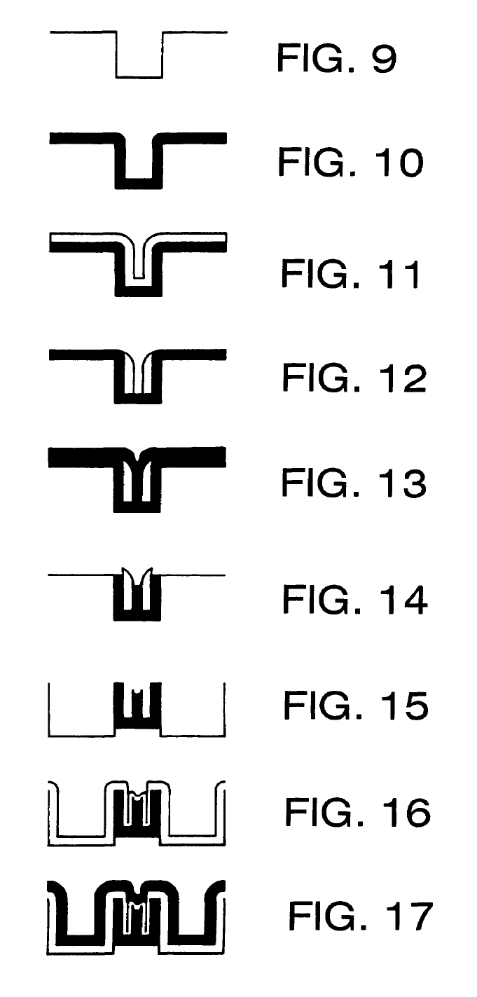

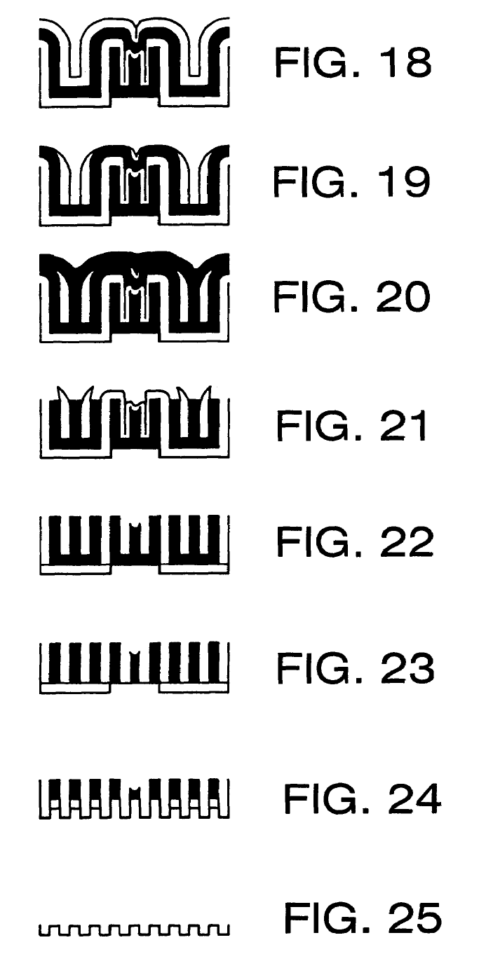

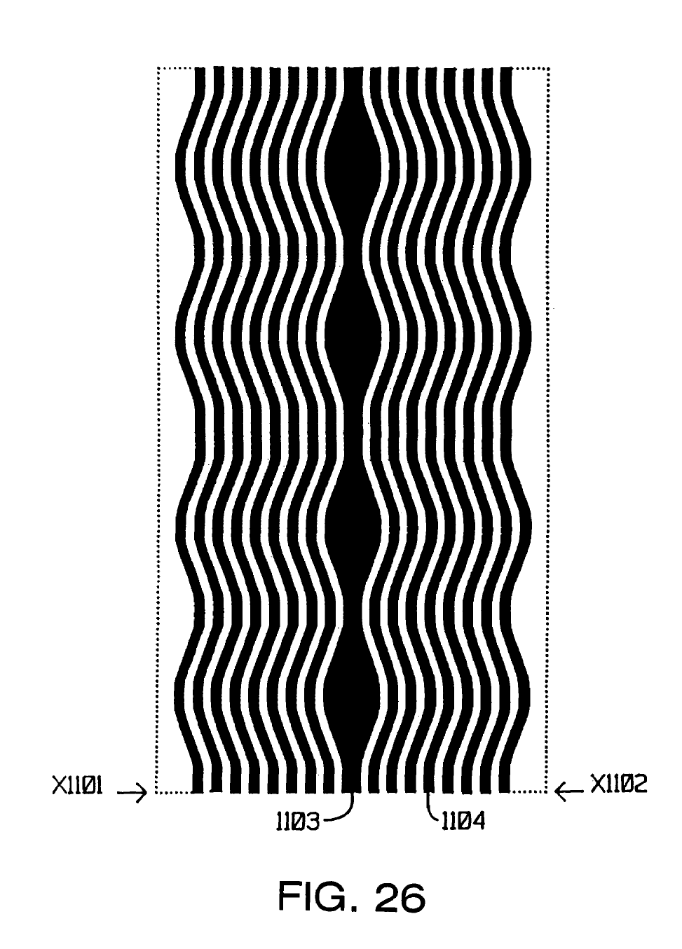

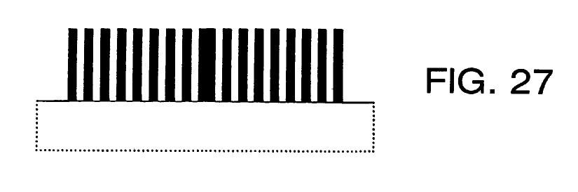

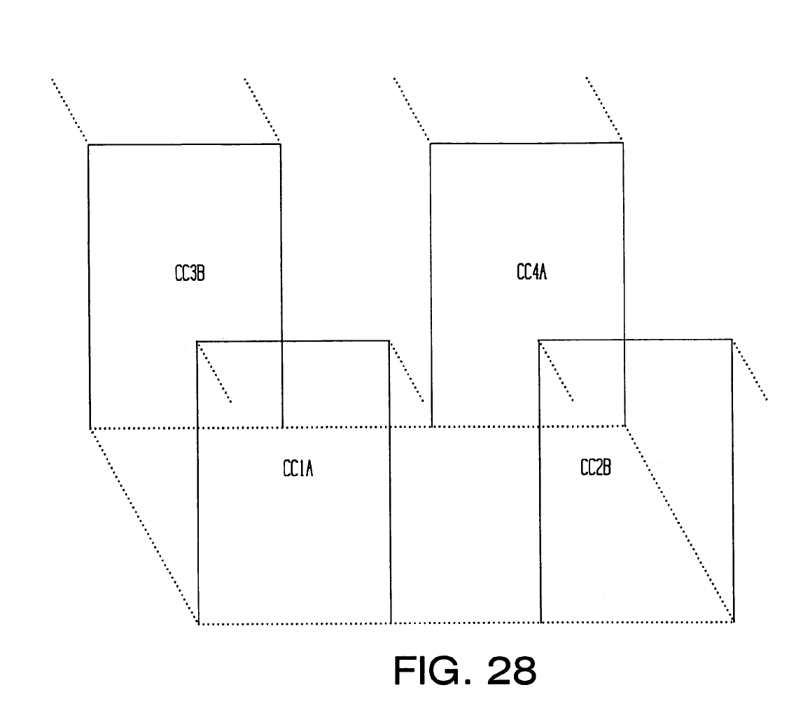

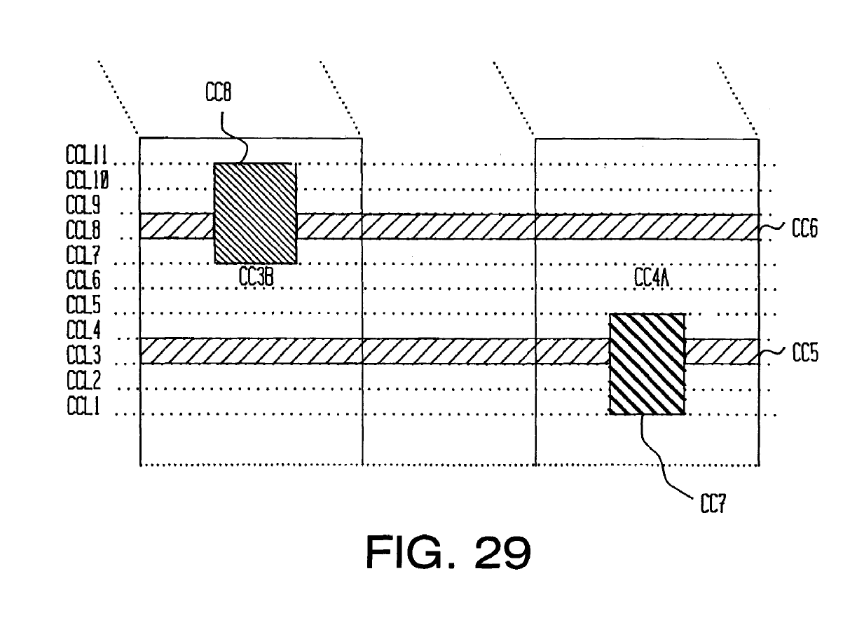

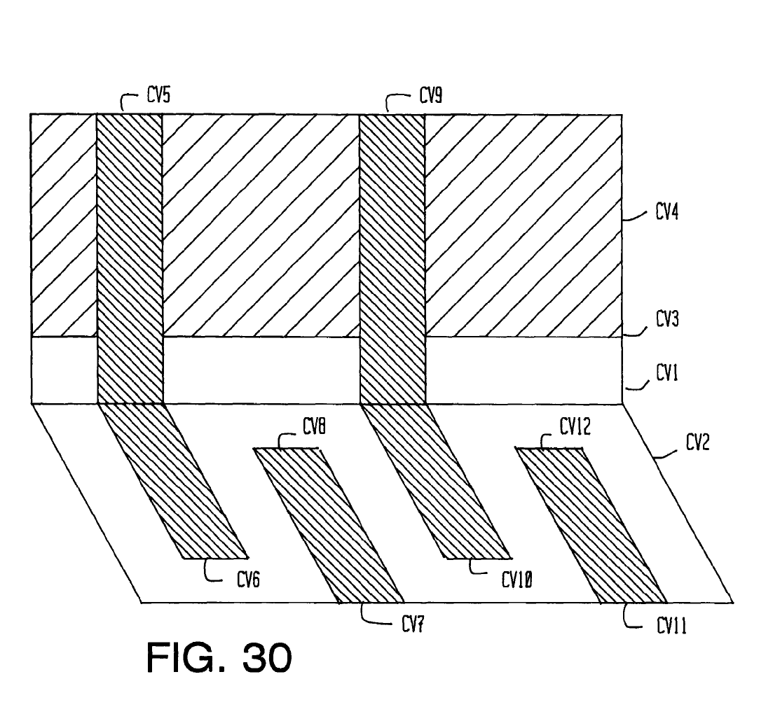

The step sequence of Part III describes 266 process steps (or step groups) to be performed on a silicon semiconductor wafer which result in the creation of one or more CMOS type static random access memory (SRAM) cells. This step sequence amounts to a process algorithm, where the step sequence of the algorithm determines the form of the semiconductor structures and w ring interconnects of a microelectronic integrated circuit. These process steps primarily involve the controlled deposition and etching of selected materials. Groups of these steps are used to fabricate specific structures which, taken together, comprise the complete SRAM cell. The conventional-style schematic of this cell is depicted in FIG. 1. FIG. 2 shows the schematic of FIG. 1 redrawn in the wiring and semiconductor spatial relationship of the structure of FIGS. 6, 7 and 8.

Summary of the Part and Sub-Part Headings Used in the Subsequent Description: <Par. 0450><Through Par. 0495>

In Parts II, II and IV, three types of paragraphs are typically present as follows: Paragraphs preceded by a code enclosed in brackets . . . explain the capabilities and value of the step(s) which follow . . . Paragraphs beginning with “FIG.” or “FIGS.” are process steps (which may include more than one process). These process steps are coded with parenthetic codes such as “(I),” “(LB1),” etc. These parenthetic codes are the primary step descriptors, and the FIG. numbers are expected to correspond as described in the text. Paragraphs beginning with neither brackets or “FIG(S).” are otherwise descriptive or explanatory text. Parts V and VI use similar formats, codes and descriptors where applicable.

I. Considerations Regarding the Following Description

Application:

The following integrated circuit technology is intended for and described as a method of making static random access memory (SRAM) cell arrays, although it may be extended to a variety of other IC fabrication applications and structures. The following description is intended to be instructive regarding how to fabricate a wide variety of individual structural features using described steps or described short or long sequences of steps. It will be apparent to those skilled in the art that the techniques described independently and as steps, step sequences and combinations thereof are independently applicable to a wide variety of integrated circuit structures and applications. The SRAM cell example presented is intended to provide an illustrative application for the subsequently described inventions.

Circuitry

a conventional schematic of the subsequently described SRAM cell.

the preceding conventional schematic in the format of the subsequently described pillar SRAM cell.

SRAM cell structure operation: Substrate layer 1 N is positively biased with respect to layer 2P in a conventional manner, so as to diode isolate the lower bit lines in the structure subsequently described in Part III.

Structures: <Par. 0504> <through Par. 0511>Describe items to be considered regarding the subsequently described structures, and regarding comprehending the text and drawings.

Processes: <Par. 0513> <through Par. 0529>Describe items to be considered when fabricating the subsequently described structures, and regarding comprehending the text and drawings.

Materials: <Par. 0531>Describes items to be considered regarding materials which can be used

Drawings: <Par. 0533> <through Par. 0536>Describe items to be considered regarding comprehending the drawings.

Terminology: <Par. 0538> <through Par. 0541>Describe and clarify terminology used in the text.

II. Fabrication Technology Used in the Following Step Sequence:

Vertical Masking techniques are described in <Par. 0543>″“sleeve” and “piston,” masking, and in more detail in:

Lower Trench Masking Plug fabrication considerations <Par. 0546> <through Par. 0550>;

Materials and techniques may be used as described in <Par. 0552> <through Par. 0560>,

Upper Trench Wall Masking Coating fabrication: <Par. 0562> <through Par. 0563>,

Subsequent Vertical Masking Steps: <Par. 0565> <through Par. 0567>.

Additional Vertical Masking Options and considerations are described in <Par. 0569> <through Par. 0576>.

III. SRAM Cell Fabrication Step Sequence

Initial Steps:

Discuss the initial creation of multiple epitaxial layers

Fabrication of Lower Bit Lines is described in <Par. 0582>-<Par. 0639>, noting that:

{LB-13} A s miconductor wafer may be trench etched to create pillars which will contain the various doped continuous crystal regions and junctions which are used to form multiple stacked transistors. <Par. 0582>

{LB-2} A second accurately etched material such as reflowed Parylene (other than the trench wall or bottom material) may be used to set a more precise vertical level than that of the trench bottoms, in an inaccurately or nonuniformly etched group of trenches.

{LB-6} A pillar side wall protector may be formed in a single trench axis, by deposition of an alternate selectable material which closes together in the first axis, followed by etching back a remaining gap in the second axis.

{LB-7} Parylene may be used as a pillar side wall protector by filling trenches with it in a single trench axis. <Par. 0587> <through Par. 0588>

{LB-8} One trench axis may be etched deeper than another without use of photolithography. <Par. 0590> <through Par. 0585>

{LB-8A} One or more sides of a pillar may be thermally oxidized to serve as gate insulation layers which extend in a vertical plane.

{LB-8B} A protective coating may be deposited over a vertical gate insulation coating, so as to allow further processing of a pillar circuit without damage to the vertical gate insulation coating in subsequent steps.

{LB-8C} The tops and bottoms of an omni-directional deposition of a gate layer material can be etched away only in the vertical axis, so as to leave material for gate insulation of multiple pillar transistors extending only over the vertical surfaces of the pillars. <Par. 0599> <through Par. 0612>

{LB-9} A trench may be partially filled with an insulator so as to make an insulative plug, so as to provide insulation between lower conductive regions of adjacent pillars.

{LB-10} An insulative plug may be fabricated by creation of vertically extending fingers made of the plug material, followed by joining these fingers together by deposition of a fill between them, followed by etching away of the thin layer of upper exposed plug material, resulting in a continuous plug which has the height of the vertically extending fingers. <Par. 0615> <through Par. 0622>

{LB-11} Two narrower regions at the bottom of a trench can be closed out, followed by omni-directional wet etch or dry etch-back of the top, so as to create a low plug-like feature in the bottom of a trench. <Par. 0624> <through Par. 0626>

{LB-12} Thus, groups of conductive bit lines on horizontal planes can be constructed below the upper surface of a semiconductor wafer (significantly below the height of the pillar tops) to control a semiconductor memory (as will be subsequently described), without the use of photolithography.

Discuss the creation of a Center Partition, in this case in conjunction with fabrication of lower bit lines, noting that:

{LB-13} A center partition can be created in the middle of a trench without use of photolithography.

{LB-14} A center partition can be created by coating the sides of a trench with a highly selectable material, filling the interstice with partition material, then removing the aforementioned highly selectable material on the sides of the partition.

{LB-15} Parylene is a preferred highly selectable material for the sides of such a partition. <0632><through 0633>

{LB-15A} A mechanically supportive base can be created for a vertically extending structure made from subsequently deposited materials.

{LB-15B} A mechanically supportive base can be created for a center partition.

Describe the creation of Lower Word Lines, noting that:

{LW-1} A center partition may be used to cause a wide trench to close out before narrower trenches.

{LW-2} Trenches which are narrower and wider may be caused to close out while leaving trenches of an intermediate size open. <Par. 0643>

{LW-3} A material coating the sides of a center partition in a vertical trench may be etched back at intermittent locations in the horizontal axis without use of photolithography, so as to expose intermittent portions of the sides of the center partition. <Par. 0645>

{LW-4} Center partitions crossing an otherwise continuous trench may be etched away, so as to make the trench continuous. <Par. 0647>

{LW-5} Alternating trenches may be etched so as to make them deeper than intervening alternating (adjacent) trenches without use of photolithography. <Par. 0649> <through Par. 0655>

{LW-6} Oblique angle directional deposition can be used to coat regions at tops of trenches, while not coating down into trenches.

{LW-6A} Such oblique angle directional deposition can be achieved by collimated sputtering from a sputtering source with collimator.

{LW-6B} Such oblique angle directional deposition can be from an evaporative source.

{LW-7} A protective coating may coat the top of a trench but not the bottom of a trench, so as to mask the top portion but not the bottom portion. <Par. 0660> <through Par. 0662>

{LW-8} A selected material may be removed from the bottom of a trench while not removing it from the top of the trench.

{LW-9} Material coating the sides of a trench may be removed only at the bottom of the trench, so as to make a narrow undercut which has a width which is approximately equal to the thickness of the coating. <Par. 0665> <through Par. 0666>

{LW-10} An undercut may be filled with an omni-directional deposition so as to close it out.

{LW-11} A feature may be created at the bottom of a trench; by close-out of a deposition below an overhanging material, followed by etch-back of the exposed portion of the deposition, followed by removal of the overhanging material.

{LW-12} An insulated region may be created at the bottom of a trench by close-out of a deposition below an overhanging material, followed by etch-back of the exposed portion of the deposition, followed by removal of the overhanging material.

{LW-13} An insulation region dividing two vertically extending conductive regions (to be subsequently described) in a trench may be created by the aforementioned method. <Par. 0671> <through Par. 0674>

{LW-14} SIMOX implantation of the bottoms of a pillar-trench array can provide an insulative layer at the bottoms of the trenches of this array. <Par. 0676>

{LW-15} A conductor may be deposited along vertical trench walls above horizontal insulative extensions in a trench, the deposited conductor being horizontally narrower than the insulative horizontal extensions below it, this deposition of conductor being followed by etching away of the tops and bottoms of the conductor, thereby allowing the deposited conductor to be insulated from lower regions in the trench by the insulative horizontal extensions below the deposited conductor. <Par. 0678> <through Par. 0681>

{LW-17} Continuous horizontal conductive lines (circuit traces) in a trench may be created by etch-back of the upper portion of the aforementioned conductor by omni-directional wet etch or dry etch of the sides of the conductor above a lower trench masking plug.

{LW-18} Control lines for FET gates may be created by the above method.

{LW-19} Word lines for a memory may be created in a trench by the above method. <Par. 0685> <through Par. 0686>

{LW-20} As a result of the foregoing steps, groups of conductive word lines on horizontal planes can be constructed below the upper surface of a semiconductor wafer to control a semiconductor memory, without the use of photolithography.

{B-23} A coating may be omni-directionally deposited in a trench above and below a step which narrows the trench, so that the lower area will close out before the upper area, thereby allowing more rapid more precisely controlled etch-back of the upper area.

{LW-21} An insulator may be created between two adjacent horizontal conductors in a trench by close-out of an insulative deposition between the conductors, followed by omni-directional wet etch or dry etch-back of insulative material coating higher portions of the trench. <Par. 0690> <through Par. 0696>

{LW-22} Trenches of two narrower sizes may be closed out with a deposited material so as to leave trenches of a third wider size open.

{LW-2} Parylene is preferred for the aforementioned deposited close-out material. <Par. 0699> <through Par. 0700>

{LW-24} When a first selectable material coating the walls of a trench is itself coated with a second material, the tops and bottoms of the first and second trench coating materials may be etched away, followed by coating the second coating material with a third coating material which will select with the first coating material (and which may be the same material as the first coating material), so that the tops of the first and third coating materials can be etched down from the top during the same etching step.

{LW-25} The aforementioned method may be used as a means to fabricate walls and a center partition of materials of the same selectivity in a trench.

{LW-26} Walls coated on trenches extending in a first axis may be used so as to enclose regions between pillars in an axis orthogonal to the first axis. <Par. 0704> <through Par. 0710>

{LW-27} Trenches may be capped in a first axis, while leaving trenches (or trench holes) uncapped in an orthogonal axis.

{LW-28} Trenches may be capped in a first axis, while uncapping alternating trenches (or trench holes) in an orthogonal axis.

{LW-29} Narrower and wider trenches can be caused to remain capped when an intermediate width trench is uncapped. <Par. 0714> <through Par. 0719>

B Trench:

{B-1} A protector may be used for gate oxide in a vertical trench to protect the gate from further trench processing while wiring circuits in the trench. <Par. 0722>

{B-2} An upper trench wall masking coating can be used to mask a first material for etching, where this first material in turn masks a second material for etching.

{B-2A} A lower trench masking plug and upper trench wall masking coating can also be used to mask a first material for etching, where this first material in turn masks a second material for etching (not shown, but as follows except with the lower trench masking plug not etched down so far as to be eliminated). <Par. 0725> <through Par. 0729>

{B-3} When a first material extends vertically up and down the walls of a trench, where this first material is coated with a second material where the thickness of this second material overhangs lower portions of the trench, and where the first material also extends out horizontally beneath the bottom of the second material so as to form an “L,” when this first material is exposed at the top of the trench, this exposed upper portion of this first material may be coated over by a directional deposition of a third material which is selectable against the first material (which third material may be the same as the second material), so as to make the lower portion of the first material which is exposed below the overhang material accessible to back- or undercut-etching, while the top portion of the first material remains protected from the etchant.

{B-4} Parylene is preferred as such a first material. <Par. 0732> <through Par. 0736>

{B-5} A short horizontal insulative tab may be created which contacts a pillar side wall at the bottom of a trench by deposition of insulative material which closes out between an overhanging material above it and the bottom of the trench, where this deposition is followed by removal of the extraneous insulative material and overhanging material. <Par. 0738> <through Par. 0741>

{B-5A} A short horizontal conductive tab may be created which contacts a pillar side wall at the bottom of a trench by deposition of conductive material which closes out between an overhanging material above it and the bottom of the trench, where this deposition is followed by removal of the extraneous conductive material and overhanging material. <Par. 0743> <through Par. 0755>

{B-7} A first material coating the walls of a trench can have the upper and lower horizontal surfaces removed so that the remaining first material extends vertically up and down the walls of the trench and overhangs the lower portion of the trench, thus exposing a conductor which wrapped down the sides of the trench a d around beneath the first material. <Par. 0757>

{B-8} Such a conductor can be etched back to the thickness of the overhang so that the thickness of the overhang serves to pattern a feature. <Par. 0759> <through Par. 0761>

{B-9} An upper portion of a conductor can be selectively separated from a lower outward extending conductor to allow circuit contact variations before later conductive relinkage between the two.

{B-10} A selectable lower trench masking plug may be set at a preferred height so as to protect unlinked lower exposed conductive regions to permit etching above these regions without damage to them. <Par. 0764>

{B-11} Wiring material may be used as a vertically extending mask to allow selective etching of insulator on a wired pillar. <Par. 0766> <through Par. 0767>

{B-12} Insulator can be caused to vary in thickness along the sides of a wired pillar, so that the conductive wiring will act as a gate for certain FETs, but not activate gates for other FETs adjacent to said conductive wiring. <Par. 0769> <through Par. 0773>

{B-14} A conductive coating can be deposited so that conductive traces are stood off from a pillar by various insulator thicknesses, where various separate conductive traces then become linked together into a more complete electronic circuit trace.

{{B-6} Chemical vapor deposition of tungsten is preferred as a conductive coating for the various subsequent as well as aforementioned processes due to its selectivity, refractory characteristics, and lack of circuit degradation features. <Par. 0776>

{B-15} Conductive wiring between adjacent pillars may be divided by coating the vertical sides of the pillars with a material which overhangs the lower portion of the adjacent trench, followed by vertically etching away the linking conductor between the two pillars so as to separate the wiring. <Par. 0778> <through Par. 0783>

{B-16} A conductive linkage may be separated by selective etching with a lower trench masking plug and upper trench wall masking coating, so as to make more than one conductive trace running up and down the pillar. <Par. 0785>

{B-17} A selectable lower trench masking plug can be used so as to permit etching away of any extension of a conductive trace leading to the top of a pillar, so as that everything below the height of the lower trench masking plug will remain usable conductive wiring. <Par. 0787>

{B-18A} Thus, electronic circuitry can be wired so as to connect electronic circuitry which includes a plurality of transistors, without the use of photolithography.

{B-18B} Thus, a side of a pillar of alternating doped regions of semiconductor material can be wired so as to connect electronic circuitry which includes a plurality of transistors, without the use of photolithography.

{B-19} Likewise, electronic circuitry which includes a plurality of transistors can be vertically wired beneath the surface of a semiconductor wafer, without the use of photolithography.

{B-20} Conductive traces on one or more sides of a column can be coated with an insulator which is etched back above the height of a lower trench masking plug formed from it, so as to protect the circuitry. <Par. 0792>

{B-21} Such an insulated section can be filled with a material which can tolerate voids within its closed-out regions, so as to reliably contain voids without degradation from trapped reactant gasses.

{B-22} Parylene is a preferred material for such closed-out regions. <Par. 0795> <through Par. 0797>

Caps:

{B-24} A cap above a preset level can be created in an open trench while other trenches remain capped.

{B-25} A cap of an open trench can be created by deposition and side closure (close-out), followed by etch-back of the deposition to the height of other caps.

{B-26} The height of the lower portion of a first cap can be set lower than the height of the lower portion of other caps, so that these other caps will be etched away first during top-etching of all caps. <Par. 0802> <through Par. 0803>

{B-27} The height of the bottom of a first cap can optionally be set higher than the height of the bottoms of other caps, so that the first cap will be etched away first during top-etching all caps (not shown).

{B-28} The height of the bottom of a first cap can optionally be set between the heights of the bottoms of other caps, so that the first cap will be etched away after top-etching etches away other caps with higher bottoms, but where the first cap is etched away before other caps with lower bottoms are etched away (not shown).

{B-29} The top of a cap can be etched down by ion milling.

{B-30} The tops of caps may be etched away by ion milling, so as to reduce all their heights, thereby reducing the subsequent heights of some caps, while eliminating other caps.

{B-31} The top of a cap can be etched down by wet etch or omni-directional dry etch (workable for the subsequent FIGS., but not shown).

{B-32} The tops of caps may be etched away with wet etch or omni-directional dry etch, so as to reduce all their heights, thereby reducing the subsequent heights of some caps while eliminating other caps (workable for the subsequent FIGS., but not shown). <Par. 0810>

{B-33} Uncapped trenches (in this case trench subdivisions on opposing sides of a partition) which are narrower than the other trenches may be recapped by deposition and etch-back of a capping material, so as to leave any uncapped wider trenches still exposed. <Par. 0813>

{B-34} A narrower trench can be closed and an intermediate sized trench can be opened by the aforementioned method when the widest trenches are already capped. In this case as subsequently demonstrated, “narrower” includes sub-trench widths on either side of a partition as in the C trench, rather than the original C trench width before partitioning, and “widest” refers to the B trench. <Par. 0815> <through Par. 0816>

A Trench:

{A-1} The bottom and sides of a conformal conductor coating may be etched away, so as to break connection between conductive traces on the sides of adjacent pillars where this connection crosses the bottom of an intervening trench. <Par. 0825> <through Par. 0828>

{A-2} A lower trench masking plug may be used to electrically isolate and chemically selectively protect a completed lower conductive link, while a new upper conductive link is subsequently fabricated. <Par. 0830> <through Par. 0831>

{A-4} A first selectable material may be used as a mask to create multiple features in a second intervening (sandwiched) layer of a second selectable material along the walls of a vertical trench, without use of photolithography. <Par. 0833> <through Par. 0839>

{A-5} A second conductive layer can be used to electrically connect direct contacts to a pillar surface with preexisting lower conductive layers along the sides of the vertical pillars, as an expeditious means of making wiring along the sides of the vertical pillars. <Par. 0841> <through Par. 0846>

{A-6} Along a wall of a vertical trench where a layer coated with an overhanging material wraps around below the overhanging material to make an “L,” the space between the overhang and the material in the trench vertically below it may serve as a mask for a layer of material closer to the trench wall, if the horizontal extension of the “L” is etched back to expose this material closer to the trench wall. <Par. 0848> <through Par. 0850>

{A-7} This method may be used to isolate lower circuitry on a wired pillar from upper circuitry on the wired pillar. <Par. 0852> <through Par. 0863>

Caps: <Par. 0865> <through Par. 0866>

{T3-1} A walled trench may be opened for processing by removal of the primary fill material, followed by wet etch or omni-directional dry etch of the walls.

{T3-2} A walled trench with a center partition may be opened for processing by removal of the primary fill material, followed by wet etch or omni-directional dry etch of the walls and center partition. <Par. 0869> <through Par. 0871>

C Trench Side Etching: <Par. 0873> <through Par. 0874>

{CS-1} Where a pillar interstitial structure takes the form of a tube of approximately rectangular cross-sect on, and comprises a plurality of concentric layers of selectable filled-in materials, the outer layer of the tube which contacts the pillars may be partially etched away with an omni-directional etch, so as to leave narrowed sections of this outer layer material running vertically along the sides of each opposing pillar. <Par. 0876> <through Par. 0878>

{CS-2} Where a thin conductor is sandwiched between two adjacent vertical pillar-like structures (in this case where the aforementioned tube serves as one such pillar-like structure), this thin conductor can be horizontally etched back, so as to leave a narrowed vertically extending conductive trace between the middles of said vertical pillar-like structures. <Par. 0880>

{CS-3} A gap between closely spaced adjacent vertical pillar-like structures can be filled with insulator, so as to insulate and chemically protect a narrower vertically extending conductive trace between the middles of the adjacent vertical pillar-like structures. <Par. 0882>

{CS-4} A material coating closely spaced adjacent pillars from the sides of these adjacent pillars can be etched off, so as to leave material only in the thin space between these adjacent pillars. <Par. 0884>

{CS-5} The aforementioned method can be used to insulate and protect vertically extending circuit traces along the sides of pillars where the coated material is an insulator.

Caps:

{CS-6} Caps of a first material can be replaced with caps of a second material, so as to provide caps of a different selectivity.

{CS-7} Caps of a plurality of materials can be created, so as to allow different selectivities when etching against the cap materials.

C Trench:

{C-1} A vertical stack of a plurality of stacked materials can be created in a trench.

{C-2} Such a stack can be constructed by creation of a sequence of vertically stacked regions of finger-like structures.

{C-3} If such stacked structures are created in a trench hole, the stack can be fabricated with the same process sequence, but the fingers of the finger-like structures form concentric rather than elongated patterns.

{C-4} Isolated conductive links can be created by this method.

{C-5} Adjacent regions on a vertical pillar can be conductively connected by this method.

{C-6} Vertically connected regions on a vertical pillar can be insulated by this method.

{C-7} Vertically extending regions of the same height on adjacent columns can be electrically isolated by this method.

{C-8} Power distribution lines (busses) can be created by this method.

{C-9} Gridded power distribution lines can be created through use of the combination of the above conductive traces with conductive regions in intervening pillars.

{C-10} Power plane decoupling for spike reduction can be implemented by providing closely spaced power grids within an integrated circuit, so as to form a capacitor between the grids. <Par. 0910> <through Par. 0939>

{C-11} A multi-material cap can be removed to gain access to the structures below. <Par. 0941> <through Par. 0944>

{C-12} A trench or trench hole of intermediate width can be protectively capped with a selective material while leaving trenches of greater and lesser width open.

{C-13} Such a cap can be fabricated by creation of a center partition in a trench or trench hole which is of intermediate width compared to other wider and narrower trenches on a wafer, as a means of causing this intermediate trench's (or trench hole's) early closure with a subsequent deposition which closes out. <Par. 0947> <through 951>

Upper Word Lines:

{UW-1 A} Where a first vertically extending selectable material is vertically sandwiched between walls of a second vertically extending selectable material, the first selectable material can be etched down so as to expose the walls of the second selectable material, followed by the multi-directional etching of the second selectable material to a preferred height, as indexed by the height of the first selectable material.

{UW-1 B} It is possible to recess the conductive gate layer of a vertical ga e on a vertical transistor so as to recess it from the edges of the underlying gate insulator.

{UW-1 C} It is possible to form an access window to a conductor within an insulative coating on the sides of a vertical surface in an integrated circuit, where edges of this access window extend vertically and are displaced horizontally on the vertical surface. <Par. 0965> <through Par. 1007>

{UW-2} Conductive traces on the opposing sides of a trench can be insulated by omni-directional deposition of an insulator which fills the region between them so as to fold together (close out) first between these conductive traces, and then above them, followed by etching this insulator back to a preferred height so that a remaining upper portion of this insulator serves as an insulative cap.

{UW-3} Trenches of multiple widths can be filled by deposition of a selectable material which folds together in or above the trenches, followed by etching said selectable material back to a preferred height. <Par. 1010> <through Par. 1015>

{UW-4} Thus, groups of conductive word lines on horizontal planes can be constructed for a memory at multiple vertical levels without the use of photolithography.

Upper Bit Lines:

{UB-1} Groups of conductive bit lines on horizontal planes can be constructed for a memory at multiple vertical levels without the use of photolithography. <Par. 1019> <through Par. 1020>

FIGS. 6, 7 and 8 depict the results of the preceding step where UB1 indicates the aforementioned bit lines, and the overall FIGS. 6, 7 and 8 depict a cell and surrounding region of the completed SRAM circuit.

Completed Structures:

As shown in the foregoing process step sequence:

{UB-2} Multiple layers of horizontal circuit traces in an integrated circuit can be created without the use of photolithography.

{UB-3} These multiple layers of horizontal circuit traces can be fabricated so as to extend in multiple horizontal directions.

{UB-4} An integrated circuit can be wired in both horizontal and vertical directions without use of photolithographic masks which have the pattern of this wiring.

{UB-5} An integrated circuit which includes a plurality of transistors can be constructed on a pillar which is of continuous single-crystalline structure.

{UB-6} An integrated circuit comprising multiple transistors which is constructed of components stacked vertically on continuous crystalline pillars can be wired with both multiple vertical and multiple horizontal conductive traces. This can be done without photolithography.

{UB-7} A portion of an integrated circuit comprising multiple transistors can be stacked on single-crystalline pillars, with multiple vertical interconnections between said transistors and multiple horizontal interconnections between transistors of adjacent pillars, so as to make a complex three-dimensional integrated multi-transistor circuit.

{UB-8} A complex three-dimensional integrated circuit can be constructed of groups of components which include multiple transistors whose alternately doped regions are made from continuous crystal, these multiple transistors being arranged in a first axis, this first axis extending into a first dimension, where these components are interconnected by conductive circuitry extending in a plurality of axes, said plurality of axes extending into second and third dimensions.

It will be apparent upon inspection of FIG. 2 that the lower structure (from layers 10P through 2P) extending below layer 11N, and the upper structure (from layers 12P through 20P) extending above layer 11N, are in fact the same structure wiring pattern, where the upward extending wiring pattern is the reverse image of the downward extending wiring pattern, these extensions being symmetrical in pattern.

{SCHM-1} As shown in FIGS. 2 and 6, 7 and 8 and the aforementioned fabrication step sequence, it is possible to construct a microelectronic integrated circuit where a wired vertical structure comprising at least a plurality of semiconductor devices embodies a portion (one-half in this case) of the complete circuit (such as the circuit of a memory cell), and where a plurality (two in this case) of such structures placed in close proximity (adjacent in this case) to one another are interconnected so as to create the complete circuit (as shown connected end-to-end in this example).

IV. Pillar Masking Techniques

Masks for making pillars below the lithographic limit can be created by making groups of lines in two orthogonal axes as follows:

{GRILL-1} An integrated circuit fabrication mask made up of groups of three equally spaced adjacent lines can be created without use of a photolithographic mask of these lines.

{GRILL-2} These groups of equally spaced adjacent lines can be fabricated with each group occurring in one of a plurality of parallel trenches.

{GRILL-3} Groups of three equally spaced adjacent lines can be created between prior existing groups of three equally spaced adjacent lines, all created without a photolithographic mask of any of these equally spaced adjacent lines.

{GRILL-4} Regular repetitions of etched trench and raised portions can be converted to higher spatial frequency repetitions of six trenches and raised portions for each prior trench and raised portion, without use of an intermediate photolithographic step.

{GRILL-5} Iterations of this process can allow repetitive line spacing division of parallel lines by six, in less than 18 deposition or etch steps per divide by six iteration.

{GRILL-6} These lines may be used as an integrated circuit fabrication mask.

{GRILL-7} Alternatively, by not varying or varying the sidewall deposition thicknesses in the sequence preferred, these mask lines may be fabricated with equal widths, or with unequal widths so as to make resulting lines of variable (such as alternating) widths, for example.

{GRILL-8} Substrates may be etched from such mask technology so as to form pillars in the substrate at dimensions smaller than the minimum photolithographic feature size used.

{GRILL-9} Parylene may be used as a subsequently easily removable (selectable) material when fabricating the open regions of such a mask. <Par. 1043> <through Par. 1063>

Substrates may be etched from such mask technology so as to form pillars in the substrate at dimensions smaller than the minimum photolithographic feature size used, at a smaller size than the minimum feature size used in the photolithographic steps, as follows:

{RIBBON-GROUPS-1} Multiple groups of horizontal lines of like trench and raised portion spacing (partition ribbon groups) running adjacent and approximately parallel to opposing vertical walls of a trench can be fabricated without use of a photolithographic mask, these line groups being separated from each other by a filler region between them of potentially different dimensions, so that the minimum to maximum width variation of this filler region fills the nonuniformity spacing difference between the walls of the trench.

{RIBBON-GROUPS-2} These lines may be used as an integrated circuit fabrication mask.

{RIBBON-GROUPS-3} Alternatively, by not varying or varying the sidewall deposition thicknesses in the sequence preferred, these mask lines may be fabricated with equal widths, or with unequal widths so as to make alternating width resulting lines, for example.

{RIBBON-GROUPS-4} Substrates may be etched from such mask technology so as to form pillars in the substrate at dimensions smaller than the minimum photolithographic feature size used.

{RIBBON-GROUPS-5} Parylene may be used as a subsequently easily removable (selectable) material when fabricating the open regions of such a mask. <Par. 1070> <through Par. 1081>

Substrates may be etched from such mask technology so as to form pillars in the substrate at dimensions smaller than the minimum photolithographic feature size used in accordance with the orthogonal masking technique described in the aforementioned discussion of divide-by-six grill masks.

V. Periphery

When pillar structures have been fabricated on a pitch which is at or above the available lithographic limit, then conventional lithographic interconnection means can be used to link to the various structures as desired. When connecting to higher and lower structures of the cell array, conventional V etch techniques which expose continuous features at various heights with horizontal displacement proportional to the angle of the “V” are probably the most convenient historical technique to align continuous feature ends with planar interconnection points.

In the following step sequence, many new capabilities are provided for interconnecting and accessing circuitry formed below the photolithographic limit to conventional circuitry formed at or above the photolithographic limit.

Per

It is possible to provide two patterns in a masking layer of an integrated circuit wafer by photolithographic image transfer, where the first pattern provides a first set of reference locations for elongated structures with spacings and widths below the photolithographic limit, and a second pattern which serves as a primary second reference location for the core of a wall, which in turn serves as a reference location for the end of the elongated structures and for via structures.

It is possible to provide a set of parallel, elongated structures submerged below the surface of the wafer, with widths and spacings below the photolithographic limit and aligned with the first set of reference locations, where the submerged structures consist of at least an insulated conductive trace each, the ends of which are determined in relation to the second reference location.

It is possible to provide a set of second reference locations derived from the primary second reference location by increasing the thickness of a wall, built upon the core located at the primary second reference location, in steps of well controlled thicknesses, where the locations of the edge of the wall at these thicknesses serve as the set of second reference locations.

It is possible to fabricate a set of insulated, conducting vias aligned by virtue of the first set of reference locations with the submerged structures, where each via conductor contacts one of the conductive traces.

It is possible to space the insulated, conducting vias along the conductive traces at distances larger than the photolithographic limit, where these distances are referenced to the set of second reference location and are achieved by non-photolithographic techniques of self-aligning to the core of the wall.

It is possible to provide a set of vias spaced above the photolithographic limit and contacting one by one a set of conductive traces spaced below the photolithographic limit such as to provide a fan-out structure from sublithographic dimensions to larger than minimum photolithographic dimensions. <Par. 1092> <through Par. 1178>

End:

It is possible to provide a pattern in a masking layer of an integrated circuit wafer by photolithographic image transfer, where the pattern simultaneously provides a first set of reference locations for elongated structures with spacings and widths below the photolithographic limit, and a second reference location for the end of said elongated structures and for via structures.

It is possible to provide a set of parallel, elongated structures submerged below the surface of the wafer, with widths and spacings below the photolithographic limit and aligned with the first set of reference locations of the masking pattern, where the submerged structures consist of at least an insulated conductive trace each, the ends of which are determined by the second reference location.

It is possible to fabricate a set of insulated, conducting vias aligned by virtue of the first set of reference locations with the submerged structures, where each via conductor contacts one of the conductive traces.

It is possible to space the insulated, conducting vias along the conductive traces at distances larger than the photolithographic limit, where these distances are referenced to the second reference location provided by the masking pattern and are achieved by non-photolithographic techniques of se f-aligning.

It is possible to provide a set of vias spaced above the photolithographic limit and contacting one by one a set of conductive traces spaced below the photolithographic limit such as to provide a fan-out structure from sublithographic dimensions to larger than minimum photolithographic dimensions. <Par. 1185> <through Par. 1218>

Fan:

It is possible to provide a pattern in a masking layer of an integrated circuit wafer by photolithographic image transfer, where the pattern simultaneously provides a first set of reference locations for elongated structures with spacings and widths below the photolithographic limit, and a second set of reference locations for the ends of said elongated structures and for via structures, the reference locations of the second set being spaced above the photolithographic limit.

It is possible to provide a set of parallel, elongated structures submerged below the surface of the wafer, with widths and spacings below the photolithographic limit and aligned with the first set of reference locations of the masking pattern, where the submerged structures consist of at least an insulated conductive trace each, the end of which is determined by one of the second set of reference locations.

It is possible to fabricate a set of insulated conducting vias aligned by virtue of the second set of reference locations with the ends of the submerged structures one by one, where each via conductor contacts one of the conductive traces.

It is possible to provide a set of vias spaced above the photolithographic limit and contacting one by one a set of conductive traces spaced below the photolithographic limit such as to provide a fan-out structure from sublithographic dimensions to larger than minimum photolithographic dimensions. <Par. 1224> <through Par. 1251>

On sub-lithographic dimensions: This interface allows lines and spaces fixed to ⅓ the minimum feature dimension of a lithographic process, because a line and two spaces fit into the narrowest end region of the trench, the width of which can be at the lithographic limit. In fact, the lines and spaces are only ⅓ of the width of the trench left after oxide deposition at step FAN2, which is less than ⅓ the lithographic limit. However, even assuming that the thickness control of deposited layers is much better than the dimension tolerance of photolithography, the entire photolithographic tolerance appears in the width of the center feature of each step of the taper. This center feature is an insulating spacer, except at the narrowest end where it is the conductor trace. While conductors and insulators can stand more tolerance than dimensions which determine transistor characteristics, the center spacer of the full-width trench may be a trench of the cell array, where accuracy of width is important and may require backing off from the minimum feature size possible. One of the favorable aspects is the ability of making the steps of the taper smaller than the photolithographic limit, because the different widths of the initial opening track very closely with one-another, and in a given taper the deviations of all widths of the opening from their nominal values are the same. These deviations are random from wafer to wafer, from chip to chip, and from trench to trench, with decreasing standard deviation.

On information transfer with photolithography: We are using photolithography in an unconventional way, because we transfer information regarding which of multiple vertical wiring patterns we wish to select. In our cell technology the information is contained in the width of the trenches, leading to A-, B-, C- and sometimes D-trenches. In the stepped taper, the widths convey the information on number of lines remaining, while the steps contain the information for the locations of the vertical vias. Thus, information is contained in both the horizontal and the vertical features of the taper pattern. This saves the complexities of defining via locations by thicknesses of deposited layers.

VI. Pillar-to-Pillar Interconnections

As subsequently described, it is possible to create the equivalent of a schematic cross-over or “X” connection which in this case interconnects electrical contact points at the tops of two (2) adjacent pillars. No further lithography is used to do this beyond the initial lithographic step which defined the pillars. <Par. 1256> <through Par. 1322>

As subsequently described, it is possible to selectively coat the sides of vertical structures such as pillars so as to leave coated or exposed regions in desired locations without lithography. These coated or exposed regions may be used insulate or permit electrical contact to underlying regions, thereby permitting selective electrical contact by subsequently applied wiring. <Par. 1324> <through Par. 1365>

VII. Scaling Down

In the aforementioned drawings as subsequently discussed, dimensional relationships shown in the drawings represent relative scaling of the structures shown in one anticipated embodiment. These dimensions may be varied according to engineering preference. SCALING DOWN OF WIRING PLANAR SURFACE AREA: <Par. 1368> <through Par. 1380>

Scaling Down of Power Distribution:

As described earlier in the process descriptions for the 20-layer pillar memory cell (C1.12) through (C1.22), and also for the previously discussed folded-over 11-layer variation on this cell, gridded electrical power distribution conductors are created at various levels in the described integrated circuit structure. These conductors electrically connect and supply electrical power to various transistors (FETs in this case) in the integrated circuit. These conductors supply electrical power to 1, 2, 3, 4, 5 or as many as 6 transistors together on a given pillar, depending on whether one considers a short section of the pillar, or all of the pillar. <Par. 1384> <through Par. 1390>

Scaling Down of Multiple Transistor Circuits:

As described earlier in the process descriptions for the 20-layer pillar memory cell (as in FIGS. 6, 7 and 8, the preceding figures, and in the supporting text for these figures), and also for the previously discussed folded-over 11-layer variation on this cell, multiple transistors (FETs in this case) are created at various levels in the described integrated circuit structure. In this structure, 1, 2, 3, 4, 5 or as many as 6 transistors are formed together on a given pillar, depending on whether one considers a short section of the pillar, or all of the pillar. <Par. 1393> <through Par. 1400>

Scaling Down of Periphery to Cell Array Interface:

As described earlier in the process descriptions for the previously discussed periphery to cell array interface, an interface is created which interconnects smaller scale conductive traces (memory cell control lines in this case) which may be fabricated below the lithographic groundrule limit to larger scale circuitry (peripheral circuitry in this case) which may be fabricated at or above the lithographic groundrule limit. <Par. 1404> <through Par. 1410>

Scaling Down of Cross-Over Circuit Interconnections:

As described earlier in the process descriptions for the previously discussed folded-over 11-layer variation on the 20-layer memory cell, a cross-over interconnection is created which interconnects opposing sides of a pair of adjacent pillars. This described pair of interconnective linkages serves the schematic equivalent function of an “X” wiring interconnection. <Par. 1413> <through Par. 1422>

VIII. Cusp Reduction: <Par. 1424> <Through Par. 1426>

IX. Sub-Lithographic Capabilities

A primary described tool for sub-lithographic fabrication in this specification is the use of thin depositions on sides of pillar structures. By placing the thin depositions on the outsides of the pillars, rather than in holes as in other publicly known examples, the ability to reduce the number of masked groundrule squares for a given structure is enhanced. <Par. 1429> <through Par. 1430>

It will be apparent that these advantages apply to any number of transistors which comprise the pillar, even to a single transistor.

Artificial SOL:

X. Improved Substrate Isolation

It is possible to improve the isolation between the substrate and the bottoms of the pillar structures by using an insulator rather than a diode isolation technique as follows: The surface of a wafer (silicon in this example) is ribbon masked in a first axis so as to make trenches which are continuous for a limited distance. These trenches are similar to those previously described with the ribbon mask example, but in this case masking is also done so as to interrupt the continuous progression of the trench. The masks for these trenches may be conventional or whatever kinds of masks are desired, not just the ribbon masks of the type previously discussed, although those ribbon masks could be used in a second orthogonal axis as before, but at a decreased spatial frequency (farther apart), to create the interruptions desired in the first orthogonal axis. In any event, the engineer may select a preferred means of masking with a single mask, or with combinations of masks.

By subsequently processing these trenches in the first axis before pillars are formed by masking in a second orthogonal axis, an insulated region can be created at the bottom of what will subsequently become a row (or rows) of pillars, as follows: A first selectable material (such as silicon dioxide) is deposited on the walls of the trench above a second selectable piston material (such as Parylene or resist), and the tops and bottoms of the sleeve deposition are removed by vertical directional etching as discussed earlier, leaving a sleeve as in the earlier examples. The second selectable piston material is then etched down to a slightly lower height, exposing the sides of what will become the bottoms of the pillars. As long as the trenches do not extend for too long a distance (i.e. interrupted soon enough), then the intervening lamellae of pillar material will be adequately supported at both ends, so as to permit the following operation. By next omni-directionally selectively etching away the exposed bottoms of the lamellae of pillar material, the lamellae can be made to be suspended freely between their supporting ends, where the interrupting mask pattern limited the length of the trenches.

An insulative material can then be applied so as to fill the open regions below the suspended lamellae. By applying a liquid such as resist which is subsequently hardened, and then etching it down in the manner of a piston as previously described, the remaining hardened liquid can form an insulative region below the lamellae, thereby electrically isolating them from the lower substrate, while at the same time providing them with a means of mechanical support at their bottoms. Once this has been accomplished, the lamellae can then be masked and etched in an axis orthogonal to the first trenches, leaving pillars of whatever preferred long or short length, where these pillars can be mechanically free standing (or subsequently wired or otherwise supplemented) while remaining insulated from the substrate.

Lamellae can also be masked so as to allow filling the trenches between pairs of lamellae with a selectable support material, a closed-out deposited material for example (such as Parylene, or other deposited materials mentioned earlier, or otherwise in common use) or a liquid which can be solidified (a polymer such as resist, etc.). This support material can be kept in place by masking or etch selectability against the other exposed materials, and then later removed by conventional selective etchants, or by conventional masking and using a conventional etchant to trench etch the support material against the mask. This allows the lamellae to be made much longer where desired.

Here, and elsewhere in this specification, resist (microlithographic photoresist) is mentioned as an example of a liquid phase deposited polymer material that can be solidified, which is publicly known to be used in these types of applications for reasons other than photolithographic patterning purposes. Readers not skilled in this art should be a are that the resists are used because they are polymers that are adaptable to these types of applications, not because they can be patterned by masked light.

XI. Clarifications and Supplemental Techniques

The preceding and subsequent disclosures are illustrative of general methods and structures which are not specific to the applications shown. The invention is not limited to the specific details of these illustrative examples. All materials called out are intended to be illustrative, and substitute materials can be used where desired in accordance with engineering preference.

NON-SILICON-BASED SEMICONDUCTOR MATERIALS:

BIPOLAR TRANSISTORS:

INCREASED SPEED AND POWER:

“CHEMICAL-MECHANICAL POLISHING”:

ATOMIC LAYER EPITAXY (ALE) depositions may be used as substitutes for *****

What is claimed is:

1. A method of fabrication for creating a plurality of adjacent lines, (a) each line of each said plurality of adjacent lines extending primarily along the path of a single axis on a plane which lies parallel to the predominant plane of a coincident or contiguous substrate, said predominant plane being considered nominally horizontal and the axis perpendicular to said predominant plane being considered nominally vertical, (b) each said plurality of adjacent lines being bounded on at least one side by the adjacent continuous edge of, optionally, material between trenches, additional pluralities of adjacent lines, or another trench or continuous structure, (c) where the location of each such adjacent continuous edge was previously the location of a trench reference sidewall, and said trench reference sidewall either was the edge of a previous associated patterning line which was a feature of a pattern defining a two-dimensional image which was transferred from a source not previously connected to the substrate, or said trench reference sidewall was trench etched down from the edge of a previous associated patterning line extending on a plane parallel to said predominant plane, (d) where said plurality of adjacent lines are created subsequent to, and at a higher spatial frequency than, patterning lines previously extending on a plane parallel to said predominant plane, (e) where, during the fabrication process, each said previous associated patterning line either was a trench, or was bounded on at least one side by a trench opening, (f) and where the horizontal location of at least one vertical sidewall of each such adjacent line in said plurality of adjacent lines is determined by a sequence of depositions forming an interlamination of layers which each have a deposited thickness which is substantially uniform where the lamination is laying horizontally, or substantially uniform where it is laying vertically, each such layer being of consistent vertical height where laying vertically, said layers being formed so as to be only conformal to the surface topography, (g) said layers being built up from and extending horizontally parallel to a single sidewall, said layers having continuous regions along this horizontal parallel extension which are vertically straight and vertically parallel to said single sidewall, each such layer covering all of any vertical face of its preceding layer or said single sidewall, the location of the face of said single sidewall coinciding with the face location of said trench reference sidewall, (h) such that electronic component features become created which incorporate or are derived from said plurality of adjacent lines, where said electronic component features contribute to the construction of a microelectronic component array, (i) where said associated patterning lines may be lamellar, having at least sufficient upward extension to permit the foregoing processes, and (j) where said electronic component features and such pluralities of adjacent lines can be fabricated sub-lithographically when said associated patterning lines are lithographic where features are created by algorithmic processing by only changing the atmosphere.
